(19) United States
(12) Patent Application Publication
(10) Pub. No.: US 2019/0191589 A1
(43) Pub. Date: Jun. 20, 2019

(54) Three-Dimensional Electronic Structure with Integrated Phase-Change Cooling

(71) Applicant: Google LLC, Mountain View, CA (US)

(72) Inventor: John Stuart Fitch, Los Altos, CA (US)

(73) Assignee: Google LLC, Mountain View, CA (US)

(21) Appl. No.: 15/844,462

(22) Filed: Dec. 15, 2017

(51) Int. Cl. H05K 7/20; F28D 20/02; H05K 5/00; H05K 5/04; H05K 5/02; H05K 5/06

(52) U.S. Cl. CPC H05K 7/2029; F28D 20/021; F28D 20/025; H05K 5/06; H05K 5/04; H05K 5/0213; H05K 5/0017

(57) ABSTRACT

This document describes techniques for implementing phase-change cooling in a three-dimensional structure. A three-dimensional structure having three-dimensional curvatures is fabricated to include a phase-change chamber with a fluid in a saturated thermodynamic state. As part of fabrication, specific mechanisms may be included that create a thermo-mechanical network that improves thermal performance of the phase-change chamber and also provides structural integrity to the three-dimensional structure.

### BACKGROUND

Structures that house systems containing heat-producing components, such as semiconductor components, power amplifiers, lithium batteries, and displays, often include thermal control mechanisms directed to controlling movement of heat within the system. As an example, a structure may include a thermal-control mechanism such as a heat sink with fins. In this instance a fluid, such as air surrounding the structure, interacts with the fins to provide heat transfer mechanics in the form of natural convection, removing heat generated by the system and thereby controlling movement of heat within the system. The fluid may further be forced (as part of forced-convection heat-transfer mechanics), where a fan forces the fluid across the fins in order to increase a rate of heat transfer.

Thermal control of the system may also be implemented using a chamber having phase-change thermodynamics. As part of phase-change thermodynamics, latent heat may be absorbed by a phase-change material (or PCM). If enough heat is absorbed by the PCM, the material may change, or transition, from one phase to another (e.g., a fluid transitioning from a liquid phase to a vapor phase). As part of the transition between phases, a temperature of the mixture of the phase-change material remains constant while relatively large quantities of latent heat are absorbed.

Traditionally, a phase-change chamber may be attached to a structure housing the electronic components. Phase-change mechanisms within the traditional phase-change chamber often rely on heat pipes that function along respective linear axes. Fluid, in a liquid phase and located near a hot region of a heat pipe, changes to a vapor phase, absorbing large quantities of latent heat. The vapor then seeks a lower pressure region that is near a cold region of the heat pipe, where the vapor condenses to a liquid phase and releases the absorbed quantities of latent heat. The liquid can then return, in a closed-loop fashion, to the hot region of the heat pipe for another phase-change cycle.

### SUMMARY

The traditional phase-change chamber is typically fabricated separately from the structure, adding expenses in terms of materials or construction. It is also limited in terms of the type of structure to which it might be applied, typically comprised of planar, two-dimensional (2D) surfaces. As such, the traditional phase-change chamber is not applicable to a complex and curved, three-dimensional (3D) structure housing a system of electronic components today, such as structure housing a virtual-reality headset, a personal assistant/smart speaker, a smartphone, or a gaming controller.

This document describes techniques for implementing phase-change cooling in a three-dimensional structure. A three-dimensional structure having three-dimensional curvatures is fabricated to include a phase-change chamber with a fluid in a saturated thermodynamic state. As part of fabrication, specific mechanisms may be included that create a thermo-mechanical network that improves thermal performance of the phase-change chamber and also provides structural integrity to the three-dimensional structure.

An example operating environment including a three-dimensional structure with integrated phase-change cooling is first described. The described operating environment is directed to managing a movement of heat of the three-dimensional structure via a phase-change chamber having a thermo-mechanical network or wicking features.

Secondly, techniques for integrating phase-change cooling into a three-dimensional structure are described. One described structure includes a first skin and a second skin having complementary, formed three-dimensional curvatures and sealed around a perimeter to form a chamber; a fluid within the chamber in a saturated thermodynamic state that induces a first region having a liquid and a second region having a vapor. A thermo-mechanical network that improves thermal behavior of the chamber and provides structural integrity to the structure is also fabricated. Another described structure includes a chamber that has surfaces with three-dimensional curvatures, a fluid within the chamber in a saturated thermodynamic state that includes a first region within the chamber having a liquid and a second region within the chamber having a vapor. Included as part of the other described structure is a wicking mechanism that is capable of transporting the liquid from the first region to a thermally-conductive interface within the second region. Also described as part of the techniques is a method for fabricating a structure having integrated phase-change cooling. The method includes forming a first skin to have sections with curvatures that are three dimensional, forming a second skin to have other sections with other curvatures that are three dimensional and complement the curvatures of the sections of the first skin, and sealing a portion of a perimeter that is common to both the first skin and the second skin in order to form a partially sealed chamber. The method continues to include dispensing fluid in liquid state into the chamber and inducing the fluid into a saturated thermodynamic state. Another portion of the perimeter is then sealed, effective to join the first skin to the second skin and complete sealing of the chamber.

Thirdly, additional example operating environments having three-dimensional structures with integrated phase-change cooling are provided.

The described aspects apply to a three-dimensional structure with integrated phase-change cooling. The details of one or more aspects are set forth in the accompanying drawings, which are given by way of illustration only, and the description below. Other features, aspects, and advantages will become apparent from the description, the drawings, and the claims.

### BRIEF DESCRIPTION OF THE DRAWINGS

The details of one or more aspects of are described below. The use of the same reference numbers in different instances in the description and the figures may indicate like elements.

FIG. 1 illustrates an example operating environment that includes a three-dimensional structure having integrated phase-change cooling.

FIG. 2 illustrates an exploded section view highlighting details of an example first skin and a second skin having complementary, three-dimensional curvatures.

FIG. 3 illustrates an exploded section view highlighting details of a structure having integrated phase-change cooling.

FIGS. 4A and 4B illustrate cross-section views of example mechanisms that may be included as part of a thermo-mechanical network.

FIG. 5 illustrates example configurations and mechanisms of a phase-change chamber in accordance with one or more aspects.

FIG. 6 illustrates other example configurations and mechanisms of a phase-change chamber in accordance with one or more aspects.

FIG. 7 illustrates an example method for fabricating a three-dimensional structure having integrated phase-change cooling.

### DETAILED DESCRIPTION

Structures housing heat-producing components, such as a virtual reality headset, a personal assistant/smart speaker, a smartphone, or gaming controller, are often shaped with complex, three-dimensional (3D) curvatures. As part of manufacturing such a structure and using specific techniques, phase-change mechanisms using a phase-change material (PCM) may be integrated as part of the structure, improving thermal control over the electronic system that might otherwise rely on convection or conduction based mechanisms.

A phase-change material (PCM) may be a fluid such as water, alcohol, or a refrigerant. The fluid may be in the form of a liquid, a vapor, or a combination of both. Furthermore, although a single fluid may be easiest to implement, mixtures of fluids may enhance thermal performance by altering surface tensions and allowing boiling to initiate more smoothly without excessive surface temperatures. Depending on a desired outcome, the fluids associated with a phase-change mechanism may be miscible or immiscible.

A chamber that is sealed and has three-dimensional curvatures can be fabricated using a variety of techniques, including joining two skins formed with complementary three-dimensional curvatures, shaping a chamber after joining two skins, or folding a single skin to shape the chamber. While partially sealed, the chamber is filled with a phase-change material in a saturated thermodynamic state (e.g., a fluid in a mixture of liquid and vapor phases). The chamber is then sealed to form a phase-change chamber.

As part of the manufacturing technique, certain mechanisms may also be integrated into the structure. For example, dimples, ridges, or channels can be intentionally formed as part of the skins and not only improve mechanical rigidity of the structure, but also improve thermal performance of the structure by serving as conduction paths, condensation points, or fluid channels that are used as part of phase-change thermodynamics. As another example, wicking mechanisms may be integrated into structure transport fluid to thermally-conductive interface locations.

Mechanisms may further be directed along distinct, non-linear axes, as dictated by the three-dimensional nature of the structure in contrast to phase-change mechanisms in use today.

The following discussion describes an operating environment and techniques that may be used for integrating, as part of a three-dimensional electronics structure, phase-change cooling mechanisms.

### Operating Environment

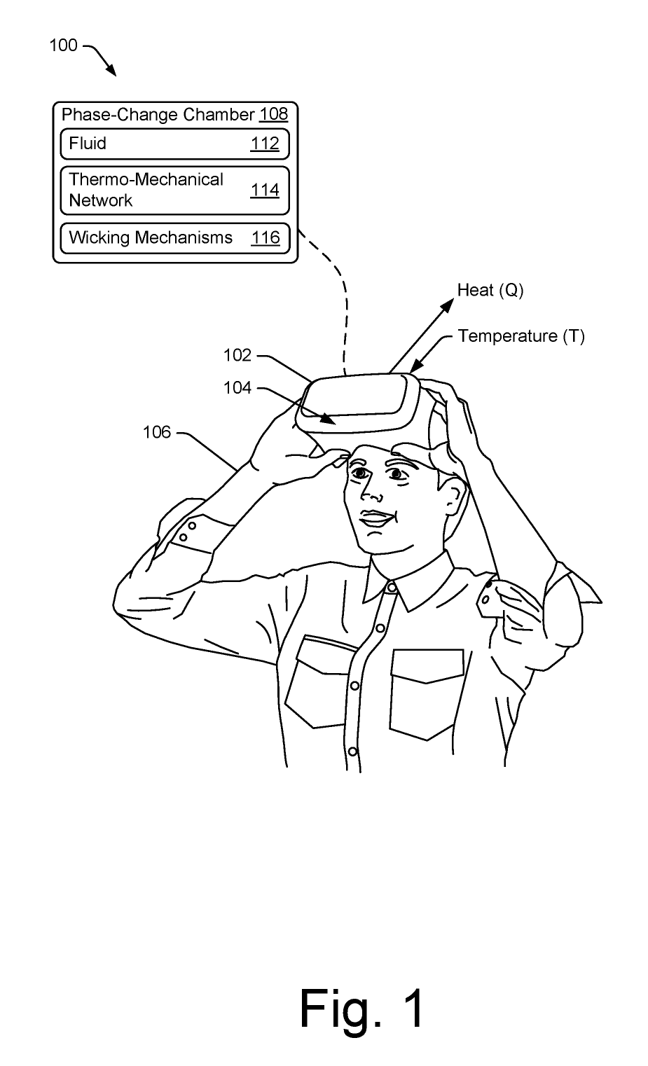

FIG. 1 illustrates an example operating environment 100 that includes a three-dimensional structure having integrated phase-change cooling. In FIG. 1, a three-dimensional (3D) structure 102 is in the example form of a virtual-reality headset. The 3D structure 102 has at least one section, such as section 104, with three-dimensional curvatures.

The 3D structure 102 is being used by a user 106. A variety of electronic components integrated into the 3D structure 102 may generate energy in the form of heat (Q), which needs to be controlled for comfort or safety reasons. For instance, using the example illustrated virtual-reality headset, a display of the virtual reality headset or a lithium battery may be generating heat (Q) within one or more localized regions of virtual-reality headset, and in order to maintain a comfortable and safe temperature (T) for the user, the heat needs to be absorbed, distributed, and then dissipated to the surroundings by the virtual reality headset.

Integrated into the 3D structure 102 is a heat transport mechanism in the form of a phase-change chamber 108 that is sealed and contains a fluid 112 in a saturated, thermodynamic state. The phase-change chamber 108 also includes a thermo-mechanical network 114 and/or wicking mechanisms 116. The thermo-mechanical network 114 and the wicking mechanisms 116, in combination, serve to enhance structural rigidity of the 3D structure 102 and improve thermal performance of the phase-change chamber 108. As heat is generated by electronic components attached to the 3D structure 102, the phase-change chamber 108 controls the temperature (T) of the 3D structure 102 via thermodynamic operations within the chamber, including absorbing latent heat if portions of the fluid 112 change from a liquid phase to a vapor phase as well as controlling movement of heat within the 3D structure 102. As part of controlling movement of heat within the 3D structure 102, the phase-change chamber 108 redistributes heat across a variety of thermal interfaces to the 3D structure 102 to enable other heat transfer mechanics, such as convection and radiation of heat from surfaces of the 3D structure 102. Other devices that may be in contact with the 3D structure 102 may also absorb heat via heat conduction.

The 3D structure 102 is illustrated in the form of the virtual-reality headset by way of example only. Other example forms of the 3D structure 102 include a personal assistant/smart speaker, a smartphone, a gaming controller, and the like.

Techniques for Integrating Phase-Change Cooling as Part of a Three-Dimensional Structure

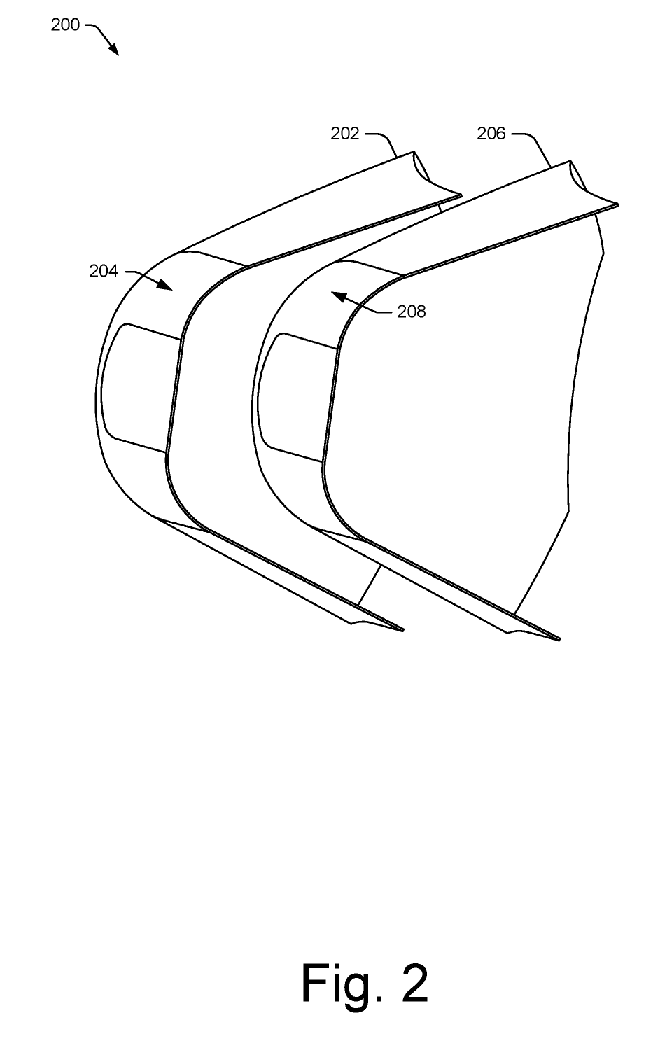

FIG. 2 illustrates an exploded section view 200 highlighting details of an example first skin and second skin that may be used as part of a structure having an integrated phase-change cooling mechanism. As part of a fabrication method that creates a structure having an integrated phase-change cooling mechanism, a forming operation is performed in accordance with one or more of the highlighted details.

As illustrated in FIG. 2, one or more forming operations form a first skin 202 having a section 204 with a curvature that is three-dimensional and a second skin 206 having another section 208 with another curvature that is three-dimensional. The respective three-dimensional curvatures are such that if the first skin 202 and the second skin 206 are brought within close proximity of one another, an offset (or “gap”) between an inner surface of the first skin 202 and an outer surface of the second skin 206 would be present, rendering the three-dimensional curvatures complementary. Radii defining the three-dimensional curvatures are determined in accordance with a desired offset.

The forming operations may form the first skin 202 and the second skin 206 from a metal such as a stamped metal or a plated metal. Alternatively, the forming operations may form the first skin 202 and the second skin 206 from plastic or ceramic using an injection molding, extrusion, or casting process. The forming operations may vary respective thicknesses throughout either skin, and may shape a thermo-mechanical network of mechanisms such as dimples, channels, or ridges as noted below.

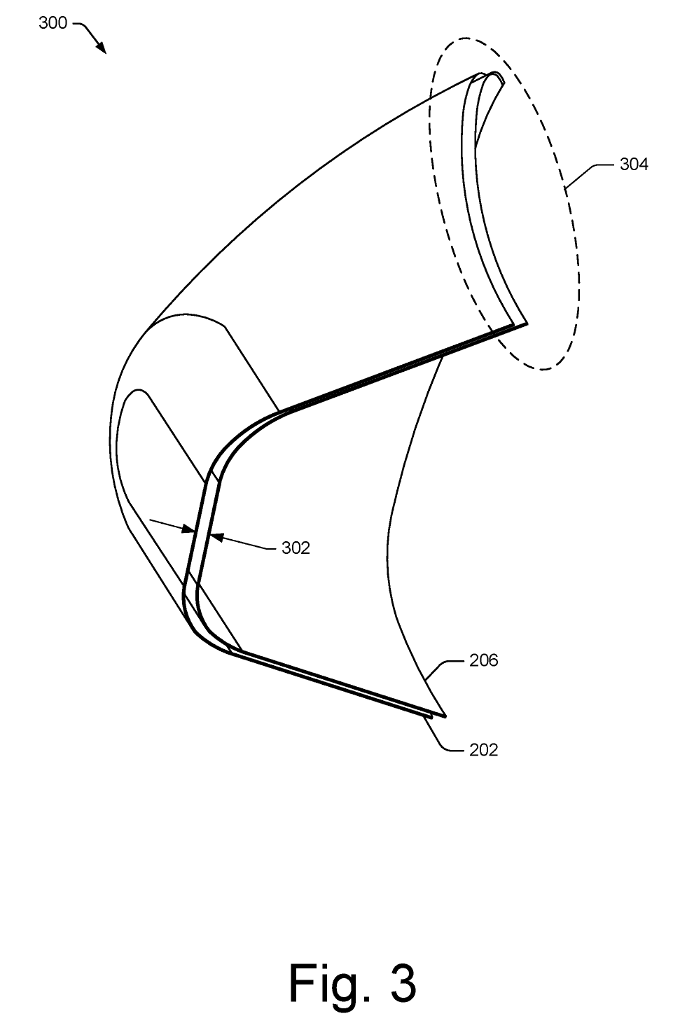

FIG. 3 illustrates an exploded section view 300 highlighting details of a structure having integrated phase-change cooling. As part of a fabrication method that creates the structure, a joining operation comprising multi-stage sealing, fluid dispensing, and inducing a thermodynamic state is performed.

As part of the joining operation, an offset 302 forms when the first skin 202 and second skin 206 are brought within close proximity of each other. Mechanical spacers, either formed as part of the skins inserted separately, may be used to implement and set spacing for the offset 302 when joining the skins. Alternatively, the offset 302 may be implemented and its spacing set using dimples, channels, or ridges as noted below. It is important to note that spacing for the offset may be either consistent or varying in nature throughout the chamber.

Also illustrated is a perimeter 304 that is common to both the first skin 202 and the second skin 206. Multi-stage sealing, using particular sealing techniques, is performed during the joining operation to seal the perimeter 304 and form a chamber. Sealing techniques may vary with materials of the first skin 202 and the second skin 206. In an instance where the materials are plastic, the sealing technique may be an epoxy or a fusion bond sealing technique. In an instance where the materials are metal, however, the sealing technique may be a welding, brazing, soldering, stir welding, or crimping technique.

Then, via the filling port, a dispensing mechanism dispenses a fluid in a liquid phase to a space between the first skin 202 and second skin 206. The fluid can be a single fluid or a mixture of fluids, such as water, alcohol, or refrigerants. Additionally, small pieces of material, such as teflon beads or metal beads, may be mixed into the fluid such that surfaces of the small pieces of material wet the fluid in ways as to enhance boiling initiation.

After the fluid has been introduced, various techniques may be used to induce a thermodynamic state of saturation (e.g., the fluid in both liquid and vapor phases) within the partially-sealed chamber. As an example, a contact heater may apply heat to a region of the partially-sealed chamber, causing a liquid portion of the fluid to vaporize and evacuate the chamber, including the purging of air or non-condensable gases. Other example techniques, any one of which may aid creation of the thermodynamic state of saturation, include a fluid bath, a vacuum, vapor injection, and radiation.

After the thermodynamic state of saturation has been created, the joining operation then performs a second stage of sealing to seal the remaining portion of the partially-sealed chamber (e.g., the filling port). In effect, and after the joining operation has been completed, a structure has been fabricated that comprises a chamber that (i) has sections with three-dimensional curvatures and (ii) contains a fluid in a saturated thermodynamic state. The chamber is, in effect, the phase-change chamber 108 integrated into the 3D structure 102 of FIG. 1.

Variations in techniques, using elements of FIG. 3, include a joining operation that seals the perimeter 304 using a single stage of sealing as opposed to multiple stages (e.g., a first stage and a second stage) of sealing. In this instance, a filling port may be created, for example, by drilling (mechanical or laser) or punching a hole in the chamber formed by the joined first skin 202 and second skin 206. Additionally, multiple filling ports may be created, allowing a fluid in an already saturated state to be flowed through the chamber and, upon being “pinched”, seal the fluid into the chamber.

The phase-change chamber 108 may also be designed and fabricated to accommodate changes in pressure that are inherent as part of vapor physics (e.g., variations in pressure or volume with changes in temperature). In certain instances, the phase-change chamber 108 may include a burst seal in the form of a thin region (e.g., a thin region of first skin 202 or second skin 206) that mechanically yields, or bursts, under a high-pressure condition. In other instances, the phase-change chamber may include a burst seal in the form of a portion of perimeter 304 that is sealed with a material that melts at an elevated temperature or yields under a high-pressure condition. Design and fabrication may also include sealing the entire perimeter 304 of the phase-change chamber 108 with a pliable material that allows the phase-change chamber 108 to expand or collapse in order to change its volume with variations in pressure.

View ports, wire ports, or mounting holes may also be incorporated into phase-change chamber 108. In such instances, the ports may be sealed using any combination of previously mentioned techniques.

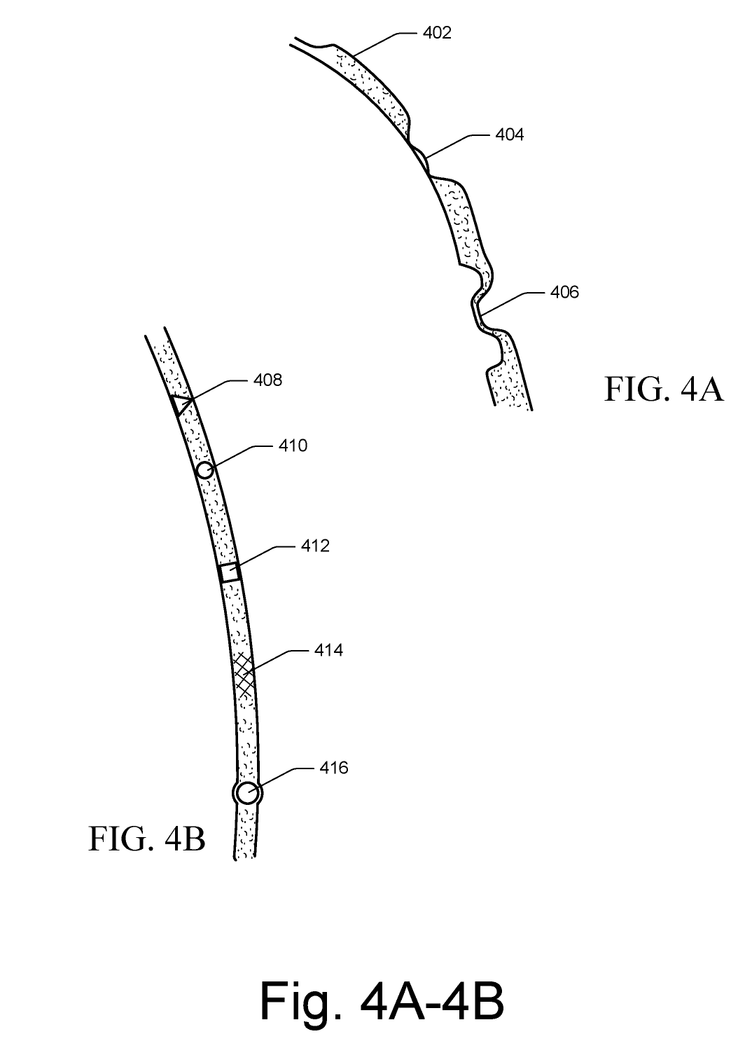

FIGS. 4A and 4B illustrate cross-section views of example mechanisms. One or more of the mechanisms may be combined to form a thermo-mechanical network. The thermo-mechanical network may be included in, and improve thermal behavior of, a phase-change chamber integrated into a 3D structure, such as the phase-change chamber 108 integrated into the 3D structure 102. The thermo-mechanical network may also provide structural integrity to the 3D structure 102.

In particular, FIG. 4A illustrates cross-sections of example mechanisms a forming process forms into skins, such as skins 202 and 206, as part of a thermo-mechanical network. Ridge 402, dimple 404, and channel 406 may each provide structural integrity to the 3D structure 102. Additionally, each mechanism may improve a thermal performance of the phase-change chamber 108 by serving as a condensation point and/or serving to distribute flows of liquid or vapor within the phase-change chamber 108. As noted earlier, the example mechanisms can further implement an offset that is either consistent or varying in nature throughout the phase-change chamber 108.

FIG. 4B illustrates cross-sections of example mechanisms an installation process may install into the phase-change chamber 108 during fabrication. Triangular rod 408, round rod 410, square rod 412, mesh 414, or ball 416 may be installed as part of a thermo-mechanical network. Each rod 408-412 and ball 416 may be of a like or different material having a specific property to facilitate a specific performance. For example, one mechanism may be of a corrosion-resistant material with high thermal-conductivity, such as aluminum, copper, or stainless steel while another mechanism may be of a corrosion-resistant material with low thermal-conductivity such as plastic. Mesh 414 may be a material with wicking capabilities such as a screen material or a fabric material. Mechanisms 408-416 may not only improve a thermal performance of the phase-change chamber 108 and/or provide structural integrity to the 3D structure 102, but may also serve to set offset distances between surfaces of phase-change chamber 108 during fabrication (e.g., first skin 202 and second skin 206). Furthermore, mechanisms 408-416 can be installed using techniques relying on, for example, thermo-compression, gluing, brazing, fasteners, welding, or snap-fitting.

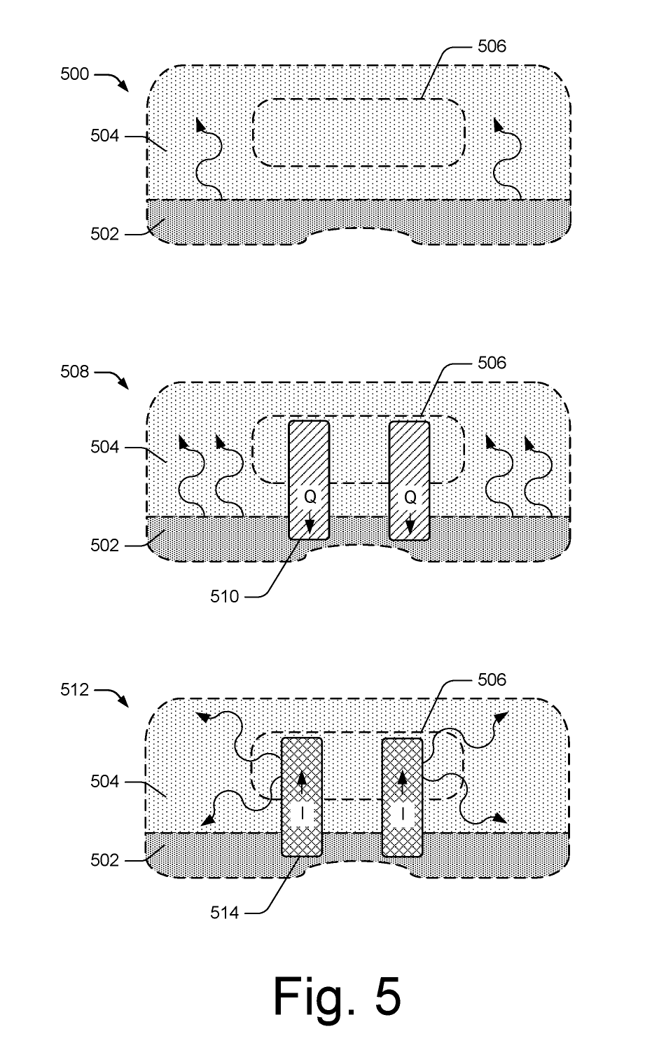

FIG. 5 illustrates example configurations of a phase-change chamber in accordance with one or more aspects. The phase-change chamber may be the phase-change chamber 108 that is integrated into the 3D structure 102 of FIG. 1. It is important to note that the example configurations, as illustrated, include two-dimensional (2D) projections of mechanisms, which may have axes that are 3-dimensional (3D) in nature.

Configuration 500 illustrates phase-change chamber 108 including a fluid in a saturated thermodynamic state. As part of the saturated thermodynamic state, a liquid region 502 and a vapor region 504 are present in the phase-change chamber 108. A hot region 506 of the phase-change chamber 108 may be within the vapor region and adjacent to an electronic component, such as a display or lithium battery, generating energy in the form of heat. As heat is introduced into the phase-change chamber 108 via the hot region 506, it may be absorbed as part of a thermodynamic phase-change process transitioning fluid from a liquid phase to a vapor phase.

Configuration 508 includes the previously described liquid region 502, vapor region 504, and hot region 506 within the vapor region 504. Further included, as part of configuration 508, is a thermo-mechanical network comprising thermal-conduction mechanisms, such as thermal-conduction mechanism 510. The thermal-conduction mechanism 510 may be in the form of a channel or ridge (such as ridge 402 or channel 406 of FIG. 4A) or rod (such as the rods 408-412 of FIG. 4B). The thermo-mechanical network is configured such that thermal contact between the thermo-mechanical network and the hot region 506 is optimized, maximizing heat (Q) conducted from the thermally-conductive interface to the liquid region 502. As a result, a thermal behavior of the phase-change chamber 108 is improved, transitioning fluid from a liquid phase to a vapor phase at a rate that would otherwise not be realized. Furthermore, the thermo-mechanical network of mechanisms (such as the thermal-conduction mechanism 510) may provide a structural integrity to the 3D structure 102 and, in certain instances, be external to the 3D structure 102.

Configuration 512 includes the previously described liquid region 502, vapor region 504, and hot region 506 within the vapor region 504. Further included, as part of configuration 512, are wicking mechanisms such as the wicking mechanism 514. The wicking mechanism 514 may be in the form of a wick, such as the mesh 414 of FIG. 4A. Design and fabrication permutations of the wicking mechanisms may accommodate a combination of materials, pore sizes, and patterns. The wicking mechanisms are configured such that the wicking mechanisms transport liquid (1) from the liquid region 502 to the hot region 506 in order for the liquid (1) to absorb latent heat and be vaporized. As a result, a thermal behavior of the phase-change chamber is improved, transitioning fluid from a liquid phase to a vapor phase (and absorbing latent heat) at a rate that would otherwise not be realized, and heat transfer is improved.

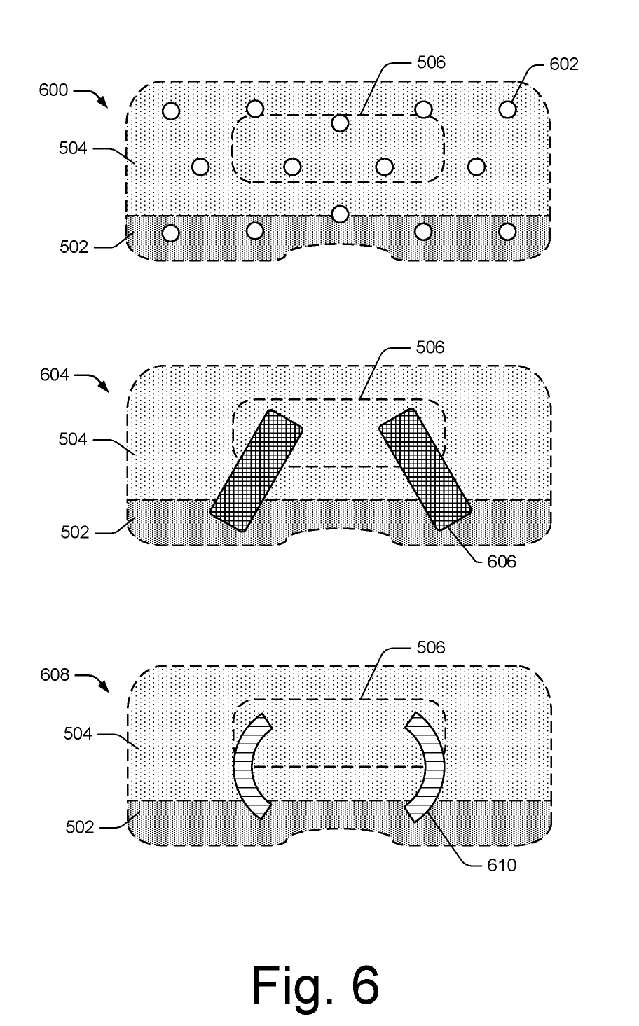

FIG. 6 illustrates other example configurations and mechanisms of a phase-change chamber in accordance with one or more aspects. The phase-change chamber may be the phase-change chamber 108 of the 3D structure 102 of FIG. 1. It is important to note that the example configurations, as illustrated, include two-dimensional (2D) projections of mechanisms that are 3-dimensional (3D) in nature.

Configuration 600 includes the previously described liquid region 502, vapor region 504, and hot region 506 within the vapor region 504. Further included, as part of configuration 600, is a thermo-mechanical network comprising a plurality of dimples, such as dimple 602. The thermo-mechanical network is configured such that the thermo-mechanical network may provide condensation points and/or distribute flows of fluids within the phase-change chamber 108.

Configuration 604 includes the previously described liquid region 502, vapor region 504, and hot region 506 within the vapor region 504. Further included, as part of configuration 600, is a thermo-mechanical network comprising mechanisms installed at differing angles, such as mechanism 606. The mechanisms, which may be in the forms of channels or ridges (such as ridge 402 or channel 406 of FIG. 4A) or rods (such as the rods 408-412 of FIG. 4B), may distribute flows of fluids within the phase-change chamber 108.

Configuration 608 includes the previously described liquid region 502, vapor region 504, and hot region 506 within the vapor region 504. Further included, as part of configuration 608, is a thermo-mechanical network comprising mechanisms of different curvatures. The mechanisms, which may have cross sections of channels or ridges (such as ridge 402 or channel 406 of FIG. 4A) or rods (such as the rods 408-412 of FIG. 4B), may distribute flows of fluids within the phase-change chamber 108.

FIGS. 2-6 illustrate and teach techniques and features that may be used individually, or in combinations, when fabricating a three-dimensional structure with integrated phase-change cooling, such as the 3D structure 102 of FIG. 1. After fabrication, electronic components may be further attached or integrated. Example electronic components include displays, combinations of semiconductor components mounted to printed circuit boards, lithium batteries, power supplies, and the like. A variety of techniques may permanently attach electronic components to the structure, such as techniques requiring hardware (e.g., swage or self-clenching nuts). Alternatively, electronic components may temporarily attach or “snap” into the structure (consider a smartphone snapping into the example virtual-reality headset (3D structure 102) of FIG. 1). As electronic components are attached to the structure, thermally-conductive interfaces (conducting heat from the electronic components into the chamber of the structure) may be optimized in terms of area, and may also include mechanism to enhance thermal conduction, such as a thermally conductive grease or silicone.

Variations may be introduced to techniques and features illustrated and taught by FIGS. 2-6. For example, in place of a fabrication method relying on a sequence of forming a first and second skin to have sections with complementary three-dimensional (3D) curvatures and then joining the skins, the first and second skin may be joined in planar form, after which forming operations may occur. As another example, a single skin may be “folded” over prior to forming operations being carried out. The three-dimensional structure may further include multiple phase-change chambers (partitioned from one another) or instrumentation for monitoring a thermodynamic state within a phase-change chamber.

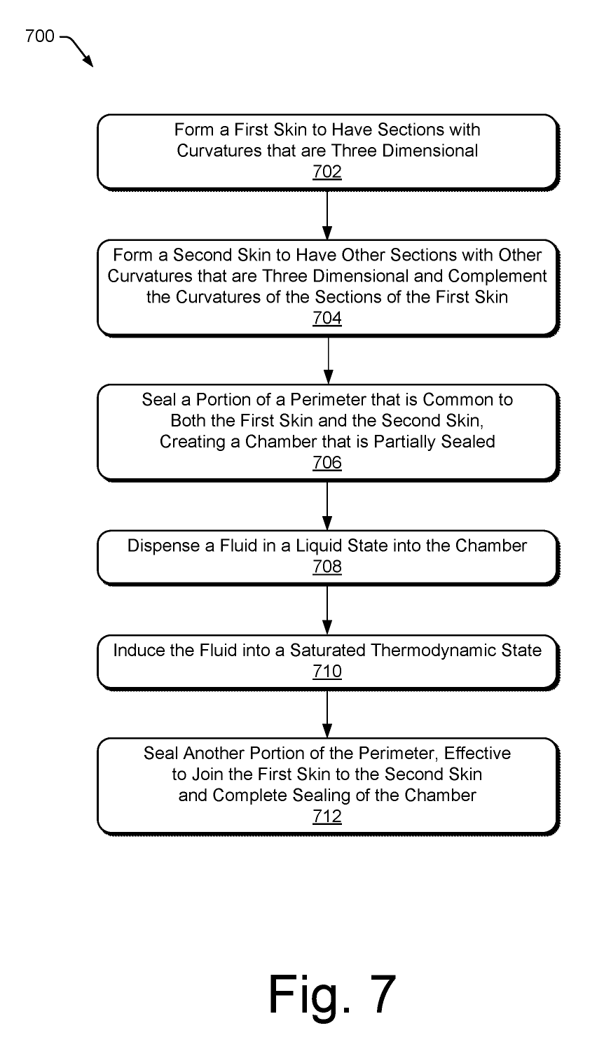

FIG. 7 illustrates an example method 700 for fabricating a three-dimensional structure having integrated phase-change cooling. The method may be performed in accordance with one or more details as highlighted in FIGS. 2-6 to yield a three-dimensional structure having integrated phase-change cooling, such as the 3D structure 102 of FIG. 1.

At stage 702, a first skin is formed to have sections with curvatures that are three dimensional. A forming operation may form the first skin from a metal such as a stamped metal or a plated metal. Alternatively, the forming operation may form the first skin from plastic (e.g., using injection molding). Furthermore, the forming operation may vary thickness throughout the first skin, and may shape a thermo-mechanical network of mechanisms such as dimples, channels, or ridges.

At stage 704, a second skin is formed to have other sections with other curvatures that are three dimensional and complement the curvatures of the sections of the first skin. A forming operation may form the second skin from a metal such as a stamped metal or a plated metal. Alternatively, the forming operation may form the second skin from plastic or ceramic. Furthermore, the forming operation may vary thickness throughout the second skin, and may shape a thermo-mechanical network of mechanisms such as dimples, channels, or ridges.

At stage 706, a portion of a perimeter that is common to both the first skin and the second skin is sealed, creating a chamber that is partially sealed. For example, a sealing technique may seal the portion of the perimeter via epoxy, fusion, welding, brazing, or crimping.

At stage 708, a fluid is dispensed into the chamber in liquid state. For example, the fluid may be water, an alcohol, or a mixture thereof.

At stage 710, the fluid is induced into a saturated thermodynamic state. Example inducing techniques include using a contact heater, a fluid bath, a vacuum, vapor injection, or radiation. At stage 712, another portion of the perimeter is sealed, effective to join the first skin to the second skin and complete sealing of the chamber.

As part of method 700, stages may be added, modified, or substituted to introduce or combine other features that may be part of a three-dimensional structure with integrated phase-change cooling. Stages may be added, modified, or substituted in accordance with descriptions of techniques and features illustrated by FIGS. 2-6.

Additional Operating Environments and Three-Dimensional Structures with Integrated Phase-Change Cooling

Techniques for integrating phase-change cooling as part of a three-dimensional structure may be applied to a variety of operating environments having systems that generate heat. The following operating environments and structures are by way of example only, and do not limit aspects to which three-dimensional structures with integrated phase-change cooling may be applied.

Example operating environments and three-dimensional structures which may include integrated phase-change cooling in accordance with one or more described aspects include: a wearable environment with systems and structures in the form of virtual-reality headset, a head-mounted display/vision system, a smart watch, or a health monitor; an automotive environment with systems and structures in the form of a navigational display or embedded computer; a personal operating environment having hand-held systems and structures in the form of gaming controllers, cameras, wireless controllers, or smartphones; an Internet-of-Things (IoT) environment having systems and structures in the form of personal-assistants, smart appliances, environmental control systems having thermostats, or security systems with remote cameras; an environment including optical or Light Detection and Ranging (LIDAR) measurement systems; and an entertainment environment having systems and structures in the form of curved televisions, wireless audio speakers, or gaming consoles.

Three-dimensional structures, in accordance with aspects described herein, may also be applied to electronic systems of military, industrial, and medical operating environments, to name but a few.

What is claimed is:

1. A three-dimensional (3D) structure, the structure comprising:
a first skin and a second skin, the first and second skin having sections of complementary, formed three-dimensional curvatures and sealed around a perimeter that is common to the first skin and the second skin to form a chamber that is sealed;
a fluid, the fluid within the chamber and in a saturated thermodynamic state that induces a first region within the chamber, the first region having a liquid, and a second region within the chamber, the second region having a vapor; and
a thermo-mechanical network, the thermo-mechanical network (i) improving thermal performance of the chamber and (ii) providing a structural integrity to the 3D structure.

2. The 3D structure as recited in claim 1, wherein the fluid within the chamber is a single fluid or a mixture of fluids.

3. The 3D structure as recited in claim 1, wherein the fluid within the chamber includes small pieces of material mixed into the fluid such that surfaces of the small pieces of material wet the fluid in ways as to enhance boiling initiation.

4. The 3D structure as recited in claim 1, wherein the thermo-mechanical network includes dimples, ridges, channels, balls, or rods.

5. The 3D structure as recited in claim 1, wherein the first skin and the second skin are formed from plastic, metal, or ceramic.

6. The 3D structure as recited in claim 1, wherein a region of the first skin or the second skin is of a varying thickness.

7. The 3D structure as recited in claim 1, wherein the 3D structure houses an electronics system.

8. The 3D structure as recited in claim 7, wherein the electronics system is a virtual-reality headset, a personal assistant/smart speaker, a smartphone, a gaming controller, a wireless controller, a camera of a security system, or a thermostat of an environmental control system.

9. A three-dimensional (3D) structure, the 3D structure comprising:
a chamber that is sealed and has sections with three-dimensional curvatures;
a fluid, the fluid within the chamber and in a saturated thermodynamic state that induces a first region within the chamber, the first region having a liquid, and a second region within the chamber, the second region having a vapor; and
a wicking mechanism capable of transporting the liquid from the first region to a hot region within the second region.

10. The 3D structure as recited in claim 9, wherein the chamber is sealed with a pliable material to enable the chamber to expand or collapse in order to change its volume.

11. The 3D structure as recited in claim 9, wherein the fluid is a single fluid or a mixture of fluids.

12. The 3D structure as recited in claim 9, wherein the wicking mechanism includes a screen or fabric material.

13. The 3D structure as recited in claim 9, further comprising a thermo-mechanical network that (i) improves a thermodynamic or heat transfer behavior of the chamber and (ii) provides structural integrity to the 3D structure.

14. The 3D structure as recited in claim 13, wherein the thermo-mechanical network includes dimples, ridges, channels, balls, or rods.

15. The 3D structure as recited in claim 1, wherein the 3D structure houses an electronics system.

16. The 3D structure as recited in claim 15, wherein the electronics system is a virtual-reality headset, a personal assistant/smart speaker, a smartphone, a gaming controller, a wireless controller, a camera of a security system, or a thermostat of an environmental control system.

17. A method for fabricating a three-dimensional (3D) structure having integrated phase-change cooling, the method comprising:
forming a first skin, the first skin formed to have sections with curvatures that are three dimensional;
forming a second skin, the second skin formed to have other sections with other curvatures that are three-dimensional and complement the curvatures of the sections of the first skin;
sealing a portion of a perimeter that is common to both the first skin and the second skin, the sealing creating a chamber that is partially sealed;
dispensing, into the chamber, a fluid, the fluid dispensed into the chamber in a liquid state;
inducing the fluid into a saturated thermodynamic state; and
sealing another portion of the perimeter, the sealing the other portion of the perimeter effective to join the first skin to the second skin and complete sealing of the chamber.

18. The method as recited in claim 17, further comprising installing a thermo-mechanical network of mechanisms that (i) improve thermal performance of the chamber and (ii) improve structural integrity of the 3D structure.

19. The method as recited in claim 17, further comprising installing a wicking mechanism that is capable of transporting a liquid from a first portion of the chamber, the first portion containing the liquid, to a second portion of the chamber, the second portion containing a vapor.

20. The method as recited in claim 17, wherein inducing the fluid into a saturated thermodynamic state is accomplished via a contact heater, a fluid bath, a vacuum, vapor injection, or radiation.
